(19) United States
(12) Patent Application Publication
(10) Pub. No.: US 2024/0361353 A1
(43) Pub. Date: Oct. 31, 2024

(54) CIRCUIT STRUCTURE, ELECTRONIC DEVICE, AND MANUFACTURING METHOD OF ELECTRONIC DEVICE

(71) Applicant: InnoLux Corporation, Miao-Li County (TW)

(72) Inventors: Kuang-Ming FAN, Miao-Li County (TW); Ju-Li WANG, Miao-Li County (TW)

(21) Appl. No.: 18/613,424

(22) Filed: Mar. 22, 2024

Related U.S. Application Data
(60) Provisional application No. 63/498,846, filed on Apr. 28, 2023.

(30) Foreign Application Priority Data
Jan. 24, 2024 (CN) 202410101430.6

(51) Int. Cl. G01R 1/073; G01R 3/00

(52) U.S. Cl. CPC G01R 1/07328; G01R 3/00

(57) ABSTRACT

A circuit structure, an electronic device, and a manufacturing method of the electronic device are provided. The circuit structure includes a support layer, a base layer, and a circuit layer. The base layer is disposed on the support layer. The circuit layer is disposed on the base layer and includes a first conductive layer, a first insulating layer, and a second conductive layer. The first conductive layer is disposed on the base layer. The first insulating layer is disposed on the first conductive layer. The second conductive layer is disposed on the first insulating layer. The elongation of the support layer is smaller than the elongation of the base layer.

### CROSS REFERENCE TO RELATED APPLICATIONS

This application claims the benefit of U.S. Provisional Application No. 63/498,846, filed 28, April 2023, and priority of China Patent Application No. 202410101430.6, filed on 20 Jan. 2024, the entirety of which are incorporated by reference herein.

### BACKGROUND OF THE INVENTION

### Field of the Invention

The present disclosure relates to electronic devices, and, in particular, to a circuit structure, an electronic device, and a manufacturing method of an electronic device.

### Description of the Related Art

In order to electrically connect or electrically test electronic elements such as wafers, dies, chips and the like, circuit structures that have probes (pins) are often used. Specifically, the probe of a circuit structure can be brought into contact with the pad (or another conductive piece) of the electronic element, and electrical testing can be performed. However, the cost of existing circuit structures is high, and the probes in these circuit structures can easily become worn or deformed. Therefore, although existing circuit structures for electrical testing have largely met their intended purposes, they do not meet requirements in all respects. Therefore, there is still a need to develop new circuit structures and electronic devices.

### BRIEF SUMMARY OF THE INVENTION

In some embodiments of the present disclosure, a circuit structure is provided. The circuit structure includes a support layer, a base layer, and a circuit layer. The base layer is disposed on the support layer. The circuit layer is disposed on the base layer and includes a first conductive layer, a first insulating layer, and a second conductive layer. The first conductive layer is disposed on the base layer. The first insulating layer is disposed on the first conductive layer. The second conductive layer is disposed on the first insulating layer. The elongation of the support layer is smaller than the elongation of the base layer.

In some embodiments of the present disclosure, an electronic device is provided. The electronic device includes a circuit structure, a bonding element, and an external element. The circuit structure includes a support layer, a base layer, and a circuit layer. The base layer is disposed on the support layer. The circuit layer is disposed on the base layer and includes a first conductive layer, a first insulating layer, and a second conductive layer. The first conductive layer is disposed on the base layer. The first insulating layer is disposed on the first conductive layer. The second conductive layer is disposed on the first insulating layer. The bonding element is in contact with the first conductive layer. The external element is electrically connected to the circuit layer through the bonding element. The elongation of the support layer is less than the elongation of the base layer.

In some embodiments of the present disclosure, an electronic device is provided. The electronic device includes the following steps. A first conductive layer is disposed on a base layer. A first insulating layer is disposed on the first conductive layer. A second conductive layer is formed on the first conductive layer, wherein the first conductive layer, the first insulating layer, and the second conductive layer collectively form a circuit layer. A support layer is disposed on the side of the base layer away from the circuit layer, wherein the elongation of the support layer is less than the elongation of the first insulating layer. A bonding element is disposed in the support layer so that the bonding element is in contact with the first conductive layer. An external element is bonded to the bonding element.

The circuit structure, electronic device, and manufacturing method of the electronic device of the present disclosure can be applied in various types of detection equipment. In order to make the features and advantages of the present disclosure more comprehensible, various embodiments are specially cited below, collectively with the accompanying drawings, to be described in detail as follows.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or mitigated for clarity of discussion.

FIGS. 1 to 7 are schematic cross-sectional views showing the circuit structure at different formation stages according to some embodiments of the present disclosure.

FIGS. 8 to 9 are schematic cross-sectional views showing the electronic device at different formation stages according to some embodiments of the present disclosure.

FIG. 10 is a schematic top view showing the electronic device according to some embodiments of the present disclosure.

FIG. 11 is a schematic cross-sectional view along the line a-a of FIG. 9 according to other embodiments of the present disclosure;

FIG. 12 is a schematic cross-sectional view along the line a-a of FIG. 9 according to further embodiments of the present disclosure;

FIG. 13 is a schematic cross-sectional view along the line a-a of FIG. 9 according to further embodiments of the present disclosure;

FIG. 14 is a schematic cross-sectional view along the line b-b of FIG. 9 according to some embodiments of the present disclosure.

FIGS. 15 to 16 are schematic cross-sectional views showing the electronic device at different formation stages according to further embodiments of the present disclosure.

FIG. 17 is a schematic cross-sectional view showing the electronic device according to further embodiments of the present disclosure.

FIG. 18 is a schematic diagram showing the use of the electronic device according to some embodiments of the present disclosure.

### DETAILED DESCRIPTION OF THE INVENTION

The following disclosure provides many different embodiments or examples for implementing the circuit structure, electronic device and manufacturing method of the electronic device. Specific examples of features and their configurations are described below to simplify the embodiments of the present disclosure, but certainly not to limit the present disclosure. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The directional terms mentioned herein, such as “up”, “down”, “left”, “right”, and similar terms refer to the directions of the drawings. Accordingly, the directional terms used is to illustrate, not to limit, the present disclosure.

In some embodiments of the present disclosure, terms about disposing and connecting, such as “disposing”, “connecting” and similar terms, unless otherwise specified, may refer to two features are in direct contact with each other, or may also refer to two features are not in direct contact with each other, wherein there is an additional connect feature between the two features. The terms about disposing and connecting may also include the case where both features are movable, or both features are fixed.

In addition, ordinal numbers such as “first”, “second”, and the like used in the specification and claims are configured to modify different features or to distinguish different embodiments or ranges, rather than to limit the number, the upper or lower limits of features, and are not intended to limit the order of manufacture or arrangement of features.

Herein, the respective directions are not limited to three axes of the rectangular coordinate system, such as the X-axis, the Y-axis, and the Z-axis, and may be interpreted in a broader sense. For example, the X-axis, the Y-axis, and the Z-axis may be perpendicular to each other, or may represent different directions that are not perpendicular to each other, but the present disclosure is not limited thereto. For convenience of description, hereinafter, the X-axis direction is the first direction D1 (width direction), the Y-axis direction is the second direction D2 (length direction), and the Z-axis direction is the third direction D3 (height direction or depth direction). In some embodiments, the schematic cross-sectional views described herein are schematic views of the XZ plane. That is, the cross-sectional direction is the direction in which the XZ plane is viewed. In some embodiments, the schematic top views described herein are schematic top views of the XY plane. That is, the top view direction is the direction in which the XY plane is viewed. The Y-axis direction is the second direction D2, which can be regarded as the normal direction of the circuit structure.

Herein, the terms “approximately”, “about”, and “substantially” generally mean within 10%, within 5%, within 3%, within 2%, within 1%, or within 0.5% of a given value or range. The given value is an approximate value, that is, “approximately”, “about”, and “substantially” can still be implied without the specific description of “approximately”, “about”, and “substantially”. The phrase “a range between a first value and a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Unless otherwise defined, all terms (including technical and scientific terms) used herein have the same meaning as commonly understood by one of ordinary skill in the art. It should be understood that these terms, such as those defined in commonly used dictionaries, should be interpreted as having meanings consistent with the background or context of the related technology and the present disclosure, and should not be interpreted in an idealized or overly formal manner, unless otherwise specified in the embodiments of the present disclosure.

In some embodiments, the electronic device of the present disclosure may include a detection device, a power module, a display device, a back light device, an antenna device, a sensing device, a privacy device, or a titling device, but the present disclosure is not limited thereto. The electronic device may be a foldable or flexible electronic device. The display device may be a non-self-luminous display device or a self-luminous display device. The antenna device may be a liquid-crystal antenna device or a non-liquid-crystal antenna device. The sensing device may be a sensing device for sensing capacitance, light, heat, or ultrasonic waves, but the present disclosure is not limited thereto. The electronic elements may include passive elements and active elements, such as capacitors, resistors, inductors, diodes, transistors, and the like. The diodes may include light-emitting diodes or photodiodes. The light-emitting diodes may include, for example, organic light-emitting diodes (OLEDs), mini light-emitting diodes (mini LEDs), micro light-emitting diodes (micro LEDs), or quantum dot light-emitting diodes (quantum dot LED), but the present disclosure is not limited thereto. The titling device may be, for example, a display titling device or an antenna titling device, but the present disclosure is not limited thereto. It should be noted that, the electronic device can be any arrangement and combination of the foregoing, but the present disclosure is not limited thereto. The content of the present disclosure will be described below with an electronic device as a display device or a titling device, but the present disclosure is not limited thereto. According to embodiments of the present disclosure, the manufacturing method of the electronic device provided can be applied, for example, to a wafer-level package (WLP) or panel-level package (PLP) process, and can adopt a chip first process or chip last (or RDL first) process, which will be explained in further detail below. The electronic device referred to in the present disclosure may include a system on package (SoC), a system in package (SiP), an antenna in package (AiP), or a combination thereof, but the present is not limited thereto.

It should be understood that, according to the embodiments of the present disclosure, the width, the thickness, or the height of each element, and the spacing of the elements or the distance between them may be measured by using a scanning electron microscope (SEM), an optical microscope (OM), a film thickness profiler (α-step), an ellipsometer, or another suitable method. In detail, according to some embodiments, a cross-sectional structure image including an element to be tested may be obtained by using a scanning electron microscope, and then the width, the thickness, the height, or the angle of each element, and the spacing of the elements or the distance between them may be measured.

It should be understood that, according to embodiments of the present disclosure, a tensile testing machine or another suitable method may be used to measure the elongation of each element. According to some embodiments, the elongation may be measured after separating each film of the present disclosure according to standards such as ASTM D638. For example, before conducting the test, two marking points may be pre-marked on the test piece of the film to be tested, wherein the distance between these two marking points is called the gage length. Then, during the testing process, the gage length will elongate, wherein the elongation=(the gage length after breakage−the original gage length before breakage)÷(the original gage length before breakage)×100%.

In some embodiments, additional features may be added to the electronic device of the present disclosure. In some embodiments, some features of the electronic device disclosed herein may be replaced or omitted. In some embodiments, additional processing steps may be provided before, during, and after the manufacturing method of the electronic device. In some embodiments, some of the described processing steps may be replaced or omitted, and the order of some of the described processing steps may be interchangeable. Furthermore, it should be understood that some of the described processing steps may be replaced or deleted for other embodiments of the method. Moreover, in the present disclosure, the number and size of each component in the drawings are only for illustration, and are not used to limit the scope of the present disclosure.

In some embodiments, the circuit structure may be used to conduct electrical testing on electronic elements such as wafers (hereinafter also referred to as the object to be tested). Specifically, the circuit structure may include probes for making contact with electronic elements. However, after undergoing multiple electrical tests, the probes of the circuit structure are prone to failure due to wear and tear. In addition, existing circuit structures are prone to accumulate stress due to impact during the process of being bonded to electronic elements, and may even become deformed and damaged. In such cases, old or damaged circuit structures (or electronic devices including them) need to be replaced frequently, which leads to an increase in the cost of electrical testing. Therefore, in order to solve at least some of the above problems, the present disclosure provides the circuit structure 1a, the electronic device 1b, and the manufacturing method of the electronic device 1b, which may have a longer service life or lower cost. In some embodiments, the circuit structure may be applied to the electrical connection relationship between electronic elements, such as a redistribution layer (RDL) structure, to redistribute the circuit fan-out or fan-in area of the chip or the size of the contact pads, but the present disclosure is not limited thereto.

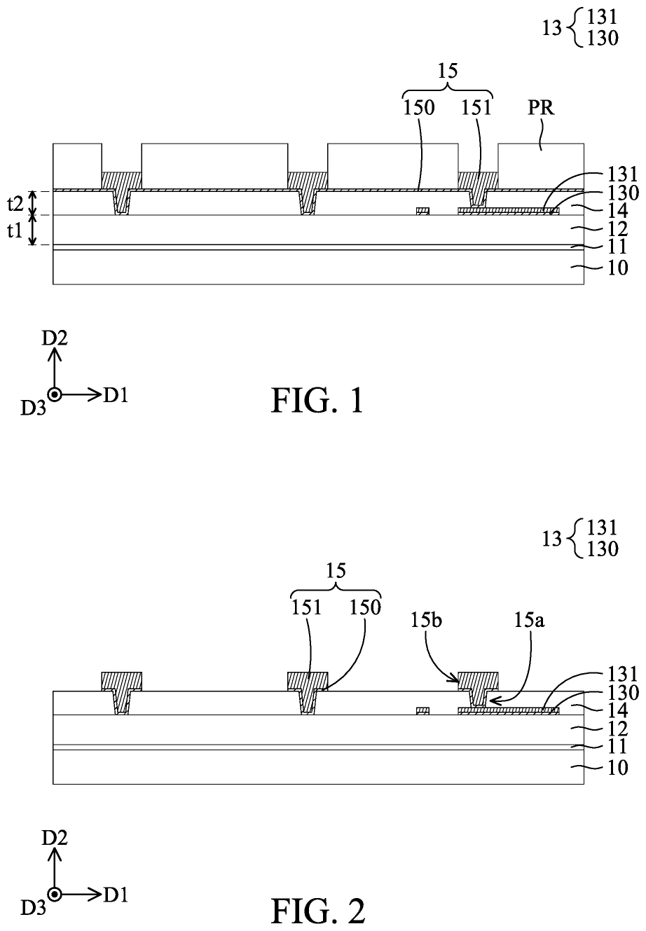

FIGS. 1 to 7 are schematic cross-sectional views showing the circuit structure at different formation stages according to some embodiments of the present disclosure. As shown in FIG. 1, the first carrier 10 is provided. Specifically, the first carrier 10 is used to carry elements located thereon, such as the base layer 12, the first conductive layer 13, the first insulating layer 14, and the second conductive layer 15 described below. In some embodiments, the first carrier 10 may include glass, silicon (Si), diamond (C), silicon carbide (SiC), sapphire, gallium oxide (Ga₂O₃), gallium nitride (GaN), aluminum gallium nitride (AlGaN), aluminum nitride (AlN), gallium phosphide (GaP), gallium arsenide (GaAs), aluminum gallium arsenide (AlGaAs), other III-V compounds, other suitable substrates, or a combination thereof, but the present disclosure is not limited thereto. For example, the first carrier 10 may be a silicon carbide substrate, a sapphire substrate, or a gallium nitride substrate.

In some embodiments, the adhesive layer 11 may be disposed on the first carrier 10, and the adhesive layer 11 is used to facilitate the detaching of the first carrier 10 and the elements (such as the base layer 12). For example, the adhesive layer 11 may be formed through a coating process or other suitable forming processes, but the present disclosure is not limited thereto. In some embodiments, the adhesive layer 11 may serve as a peeling layer or a release layer. In some embodiments, the adhesive layer 11 may be or may include pyrolytic glue, ultra-violet (UV) glue, light-to-heat conversion (LTHC) glue, or other suitable cleavable adhesive layers, or a combination thereof, but the present disclosure is not limited thereto.

Following the above step, the base layer 12 is disposed on the first carrier 10. In some embodiments, the base layer 12 has a specific elongation, and the elongation of the base layer 12 is greater than 50% (>50%) and less than or equal to 800%. For example, the elongation of the base layer 12 may be 51%, 55%, 60%, 70%, 75%, 80%, 85%, 90%, 95%, 100%, 110%, 130%, greater than 130%, or any value or range between the above values, but the present disclosure is not limited thereto. By allowing the base layer 12 to have a certain degree of elongation (for example, greater than 50%), the subsequently formed circuit structure (or electronic device) may effectively mitigate collisions during testing, thereby extending the service life of the entire device.

In some embodiments, the base layer 12 may be a single-layer film or multi-layer film. For example, the base layer 12 may be a multi-layer film including multiple sub-layers, and the material and thickness of each sub-layer may be the same or different. In some embodiments, the material of the base layer 12 may include an organic material, but the present disclosure is not limited thereto. For example, the organic material may include polyimide (PI), photosensitive polyimide (PSPI), build-up film (Ajinomoto build-up film, ABF), epoxy resin (epoxy), other suitable organic materials, or a combination thereof, but the present disclosure is not limited thereto. In some embodiments, the thickness t1 of the base layer 12 may be between 10 μm and 30 μm, but the present disclosure is not limited thereto. For example, the thickness t1 of the base layer 12 may be 10 μm, 15 μm, 20 μm, 25 μm, 30 μm, or any value or range between the above values. The thickness referred to in this embodiment is measured along the second direction D2.

Following the above step, the first conductive layer 13 is formed on the base layer 12. For example, the seed layer 130 may be formed on the base layer 12 by, for example, a deposition process. Then, the conductive layer 131 is formed on the seed layer 130 by, for example, a deposition process. Finally, part of the seed layer 130 and/or the conductive layer 131 is removed by, for example, an etching process to form the first conductive layer 13 as shown in FIG. 1.

In some embodiments, the deposition process may include physical vapor deposition (PVD), atomic layer deposition (ALD), metal-organic chemical vapor deposition (MOCVD), electroplating, other suitable deposition processes, or a combination thereof, but the present disclosure is not limited thereto. In some embodiments, the etching process may include dry etching, wet etching, other suitable etching processes, or a combination thereof, but the present disclosure is not limited thereto.

In some embodiments, the material of the first conductive layer 13 may include a metallic conductive material, a transparent conductive material, or a combination thereof. For example, the metal conductive material may include copper (Cu), aluminum (Al), molybdenum (Mo), silver (Ag), tin (Sn), tungsten (W), gold (Au), chromium (Cr), nickel (Ni), platinum (Pt), titanium (Ti), titanium nitride (TiN), other suitable metals, an alloy thereof, the like, or a combination thereof, but the present disclosure is not limited thereto. For example, the transparent conductive material may include transparent conductive oxide (TCO), such as indium tin oxide (ITO), tin oxide (SnO), zinc oxide (ZnO), indium zinc oxide (IZO), indium gallium zinc oxide (IGZO), indium tin zinc oxide (ITZO), antimony tin oxide (ATO), antimony zinc oxide (AZO), the like, or a combination thereof, but the present disclosure is not limited thereto. In some embodiments, the materials of the seed layer 130 and the conductive layer 131 of the first conductive layer 13 may be the same or different. For example, the materials of the seed layer 130 and the conductive layer 131 may include copper, wherein the seed layer may improve the bonding ability between the subsequent film and the insulating layer, but the present is not limited thereto.

Following the above step, the first insulating layer 14 is disposed on the base layer 12 and the first conductive layer 13. For example, the first insulating layer 14 may be formed by a chemical vapor deposition process (CVD), a physical vapor deposition process (PVD), an atomic layer deposition process (ALD), a spin coating process (spin coating), other suitable processes, or a combination thereof, but the present disclosure is not limited thereto.

In some embodiments, the first insulation layer 14 has a specific elongation, and the elongation of the first insulation layer 14 is greater than 50% (>50%). For example, the elongation of the first insulating layer 14 may be 55%, 60%, 70%, 75%, 80%, 85%, 90%, 95%, 100%, 110%, 130%, greater than 130%, or any value or range between the above values, but the present disclosure is not limited thereto. By allowing the first insulating layer 14 to have a certain degree of elongation (for example, greater than 50%), the subsequently formed circuit structure (or electronic device) may effectively mitigate collisions during testing, thereby extending the service life of the entire device.

In some embodiments, the first insulating layer 14 is closer to the object to be tested than the base layer 12, so the elongation of the first insulating layer 14 may be greater than the elongation of the base layer 12. Therefore, the circuit structure (or electronic device) may more effectively mitigate collisions during testing, thereby further extending the service life of the entire device. That is, the elongation of the base layer 12 is smaller than the elongation of the first insulating layer 14.

In some embodiments, the first insulating layer 14 may be a single-layer film or a multi-layer film. For example, the first insulating layer 14 may be a multi-layer film including multiple sub-layers, and the material and thickness of each sub-layer may be the same or different. In some embodiments, the material of the first insulating layer 14 may include an organic material, but the present disclosure is not limited thereto. For example, the organic material may include polyimide (PI), photosensitive polyimide (PSPI), silane coupling, other suitable organic materials (such as other photosensitive materials), or a combination thereof, but the present disclosure is not limited thereto. In some embodiments, the thickness t2 of the first insulating layer 14 may be between 10 μm and 20 μm, but the present disclosure is not limited thereto. For example, the thickness t2 of the first insulating layer 14 may be 10 μm, 12.5 μm, 15 μm, 17.5 μm, 20 μm, or any value or range between the above values. In some embodiments, the first insulating layer 14 has a thinner thickness than the base layer 12. That is, the thickness of the base layer 12 is greater than the thickness of the first insulating layer 14. Therefore, the elongation of the first insulating layer 14 may be greater than the elongation of the base layer 12 to further extend the service life of the entire device. That is, the elongation of the base layer 12 is smaller than the elongation of the first insulating layer 14.

Following the above step, then an opening is formed on the first insulating layer 14, and the opening exposes the base layer 12 and the first conductive layer 13. Then, the seed layer 150 is disposed on the first insulating layer 14, and the seed layer 150 is disposed on the base layer 12 and the first conductive layer 13 exposed from the opening.

Following the above step, the photoresist layer PR is formed on the seed layer 150. For example, the photoresist layer PR may be formed by, for example, a photolithography process, but the present disclosure is not limited thereto. Specifically, the photoresist layer PR exposes the opening of the first insulating layer 14. Then, the conductive layer 151 is formed in the opening of the first insulating layer 14, so that the seed layer 150 and the conductive layer 151 collectively form the second conductive layer 15.

In some embodiments, the material of the second conductive layer 15 may include a metallic conductive material, a transparent conductive material, or a combination thereof. For example, the metal conductive material may include copper (Cu), aluminum (Al), molybdenum (Mo), silver (Ag), tin (Sn), tungsten (W), gold (Au), chromium (Cr), nickel (Ni), platinum (Pt), titanium (Ti), titanium nitride (TiN), other suitable metals, an alloy thereof, the like, or a combination thereof, but the present disclosure is not limited thereto. For example, the transparent conductive material may include a transparent conductive oxide (TCO), such as indium tin oxide (ITO), tin oxide (SnO), zinc oxide (ZnO), indium zinc oxide (IZO), indium gallium zinc oxide (IGZO), indium tin zinc oxide (ITZO), antimony tin oxide (ATO), antimony zinc oxide (AZO), the like, or a combination thereof, but the present disclosure is not limited thereto. In some embodiments, the materials of the seed layer 150 and the conductive layer 151 of the second conductive layer 15 may be the same or different. For example, the materials of the seed layer 150 and the conductive layer 151 include copper. For example, the materials of the seed layer 150 and the conductive layer 151 may both be copper. Through the above design, the contact resistance between different films may be reduced, thereby reducing the detection error, but the present disclosure is not limited thereto. In some embodiments, the material of the second conductive layer 15 may be the same as or different from the material of the first conductive layer 13.

As shown in FIG. 2, following the above step, the photoresist layer PR and the seed layer 150 covered by the photoresist layer PR are removed. In such cases, the second conductive layer 15 includes the first portion 15a and the second portion 15b. Among them, the first portion 15a penetrates the first insulating layer 14 and is disposed on the first conductive layer 13, and the second portion 15b is disposed on the first portion 15a. Specifically, the first portion 15a is used to connect the second portion 15b and the first conductive layer 13, and the second portion 15b may be used as a probe to be in contact with the object to be tested in the subsequent detection process.

As shown in FIG. 3, following the above step, the second portion 15b of the second conductive layer 15 includes a multi-layer structure. That is, the multi-layer structure may include an inner layer disposed on the first portion 15a and an outer layer disposed on the inner layer, so that the outer layer serves as a protective layer for the inner layer. For example, since the second portion 15b of the second conductive layer 15 is used to be in contact with the object to be tested, the second portion 15b may be formed into a multi-layer structure including a softer inner layer and a harder outer layer to extend the service life of the second portion 15b. Specifically, another conductive layer 152 may be disposed on the conductive layer 151 through a deposition process, a coating process, an electroplating process, or other suitable methods, wherein the hardness of the conductive layer 152 (that is, as the harder outer layer) is greater than that of the conductive layer 151 (that is, as the softer inner layer). The hardness referred to in the present disclosure may be obtained by referring to the ASTM-E18 standard, the ASTM-E10 standard, or other appropriate standard testing methods.

In some embodiments, the conductive layer 153 may be further disposed on the conductive layer 152, wherein the hardness of the conductive layer 153 is greater than the hardness of the conductive layer 152 and the conductive layer 151 to further extend the service life of the second portion 15b. For example, the conductive layer 152 may include gold (Au), an alloy thereof, or other suitable metals, but the present disclosure is not limited thereto. The conductive pad layer 153 may include nickel (Ni), an alloy thereof, or other suitable metals, but the present disclosure is not limited thereto.

For the sake of brevity, in the following, the seed layer 150, the conductive layer 151, the conductive layer 152, and the conductive layer 153 may be collectively referred to as the second conductive layer 15. It should be noted that although the second conductive layer 15 shown in the figures of the present disclosure includes the seed layer 150, the conductive layer 151, the conductive layer 152, and the conductive layer 153, the present disclosure is not limited thereto. In other embodiments, the step shown in FIG. 3 may be omitted. In other words, the second conductive layer 15 may be composed of the seed layer 150 and the conductive layer 151 without including the conductive layer 152 and the conductive layer 153. Alternatively, in other embodiments, the step shown in FIG. 3 may be performed multiple times to form the second conductive layer 15 into a structure with more layers (e.g., more than 4 layers).

In some embodiments, the first conductive layer 13, the first insulating layer 14, and the second conductive layer 15 collectively form the circuit layer 16. In the present disclosure, the circuit layer 16 is on one side of the base layer 12 and is used for electrical testing of the object to be tested.

As shown in FIG. 4, following the above step, the second insulating layer 17 is disposed on the first insulating layer 14, and a plasma-cleaning process is performed on the second conductive layer 15. Specifically, the second insulating layer 17 is used to protect the first insulating layer 14 during the plasma-cleaning process, and the plasma-cleaning process is used to remove impurity particles on the second conductive layer 15. According to some embodiments, the material of the second insulating layer 17 may include silicon rubber, solder resist, or other suitable materials, but the present disclosure is not limited thereto.

As shown in FIG. 5, following the above step, the second insulating layer 17 may be selectively removed, and the opening 140 is formed in the first insulating layer 14. The opening 140 may penetrate the first insulating layer 14, or the opening 140 may penetrate both the first insulating layer 14 and the base layer 12. For example, the opening 140 may be formed by a laser etching process, a wet etching process, a dry etching process, other suitable etching processes, or a combination thereof, but the present disclosure is not limited thereto. According to some embodiments, the second insulating layer 17 may not be removed, an opening may be formed through a patterning step, and the opening may penetrate the base layer 12, the first insulating layer 14, and the second insulating layer 17.

As shown in FIG. 6, following the above step, the second carrier 18 is bonded onto the circuit layer 16. In some embodiments, the second carrier 18 may include glass, silicon (Si), diamond (C), silicon carbide (SiC), sapphire, gallium oxide (Ga₂O₃), gallium nitride (GaN), aluminum gallium nitride (AlGaN), aluminum nitride (AlN), gallium phosphide (GaP), gallium arsenide (GaAs), aluminum gallium arsenide (AlGaAs), other III-V compounds, other suitable substrates, or a combination thereof, but the present disclosure is not limited thereto. In some embodiments, the second carrier 18 may be similar or the same as to the first carrier 10, but the present disclosure is not limited thereto. For example, the second carrier 18 may be a silicon carbide substrate, a sapphire substrate, or a gallium nitride substrate.

In some embodiments, the adhesive layer 19 may be disposed between the second carrier 18 and the circuit layer 16, and the adhesive layer 19 is used to facilitate the detaching of the second carrier 18 and the circuit layer 16 in subsequent processes. In some embodiments, the adhesive layer 19 may serve as a peeling layer or a release layer. In some embodiments, the adhesive layer 19 may be or may include pyrolytic glue, ultraviolet photolysis (UV) glue, light-to-heat conversion (LTHC) glue, other suitable cleavable adhesive layers, or a combination thereof, but the present disclosure is not limited thereto.

Following the above step, the second carrier 18 is turned over, and the first carrier 10 is removed. For example, the first carrier 10 may be separated from the base layer 12 by removing the adhesive layer 11. Following the above step, the opening is formed in the base layer 12. The opening may include the opening 120a and the opening 120b, the opening 120a exposes the first conductive layer 13, and the opening 120b and the opening 140 are connected to each other. According to some embodiments, when the opening 140 directly penetrates the first insulating layer 14 and the base layer 12, the step of forming the opening 120b may be selectively omitted according to design requirements, but the present disclosure is not limited thereto.

As shown in FIG. 7, following the above step, the support layer 20 is disposed on the side of the base layer 12 away from the circuit layer 16. That is, the base layer 12 is between the circuit layer 16 and the support layer 20. For example, the support layer 20 may be formed by a deposition process such as a lamination process, a chemical vapor deposition process, a physical vapor deposition process, an atomic layer deposition process, a spin coating process, other suitable processes, or a combination thereof, but the present disclosure is not limited thereto. In some embodiments, the support layer 20 has a specific elongation, and the elongation of the support layer 20 is between 10% and 50%. For example, the elongation of the support layer 20 may be 10%, 15%, 20%, 25%, 30%, 35%, 40%, 45%, 50%, or any value or range between the above values, but the present disclosure is not limited thereto. By allowing the support layer 20 to have a certain degree of elongation (for example, between 10% and 50%), the subsequently formed circuit structure (or electronic device) may effectively mitigate collisions during testing, thereby extending the service life of the entire device. In some embodiments, the elongation of the support layer 20 may be smaller than the elongation of the base layer 12 to increase the strength of the overall circuit structure 1a (or the electronic device 1b including the same).

In some embodiments, the first insulating layer 14 is closer to the object to be tested than the support layer 20, so the elongation of the first insulating layer 14 may be greater than the elongation of the support layer 20. Therefore, the circuit structure (or electronic device) may more effectively mitigate collisions during testing, thereby further extending the service life of the entire device. That is, the elongation of the support layer 20 is smaller than the elongation of the first insulating layer 14.

In some embodiments, the support layer 20 may be a single-layer film or a multi-layer film. For example, the support layer 20 may be a multi-layer film including multiple sub-layers, and the material and thickness of each sub-layer may be the same or different. In some embodiments, the material of the support layer 20 may include an organic material or an inorganic material, but the present disclosure is not limited thereto. For example, the organic material may include polyimide (PI), epoxy, other suitable organic materials, or a combination thereof, but the present disclosure is not limited thereto. For example, the inorganic material may include glass, other suitable inorganic materials, or a combination thereof, but the present disclosure is not limited thereto. In some embodiments, the thickness t3 of the support layer 20 may be between 38 μm and 50 μm, but the present disclosure is not limited thereto. For example, the thickness t3 of the support layer 20 may be 38 μm, 40 μm, 42 μm, 44 μm, 46 μm, 48 μm, 50 μm, or any value or range between the above values. In some embodiments, the first insulating layer 14 has a thinner thickness than support layer 20. That is, the thickness of the support layer 20 is greater than the thickness of the first insulation layer 14. According to some embodiments, the thickness of support layer 20 is greater than the thickness of base layer 12. Therefore, the elongation of the first insulating layer 14 may be greater than the elongation of the support layer 20 to further extend the service life of the entire device. That is, the elongation of the support layer 20 is smaller than the elongation of the first insulating layer 14.

As above-mentioned, the circuit structure 1a has been formed on the second carrier 18. Specifically, the circuit structure 1a includes the support layer 20, the base layer 12, and the circuit layer 16. The base layer 12 is disposed on the support layer 20. The circuit layer 16 is disposed on the base layer 12, and the circuit layer 16 includes the first conductive layer 13, the first insulating layer 14, and the second conductive layer 15. The first conductive layer 13 is disposed on the base layer 12. The first insulating layer 14 is disposed on the first conductive layer 13. The second conductive layer 15 is disposed on the first insulating layer 14. Through the above configuration, the circuit structure 1a may be used for electrical testing of the object to be tested and has a good service life.

In order to enable the circuit structure 1a to be electrically connected to external elements such as a printed circuit board (PCB) or a flexible printed circuit (FPC), the circuit structure 1a may be further processed to form the electronic device 1b as shown below. According to some embodiments, the circuit structure 1a may be, for example, a part of a circuit board, such as a part of a flexible printed circuit (FPC). That is, the circuit structure 1a may be regarded as a flexible circuit board, and electronic elements (such as chips, resistors, capacitors, or other elements) may be bonded to the circuit structure 1a to form a chip on film (COF) package, but the present disclosure is not limited thereto.

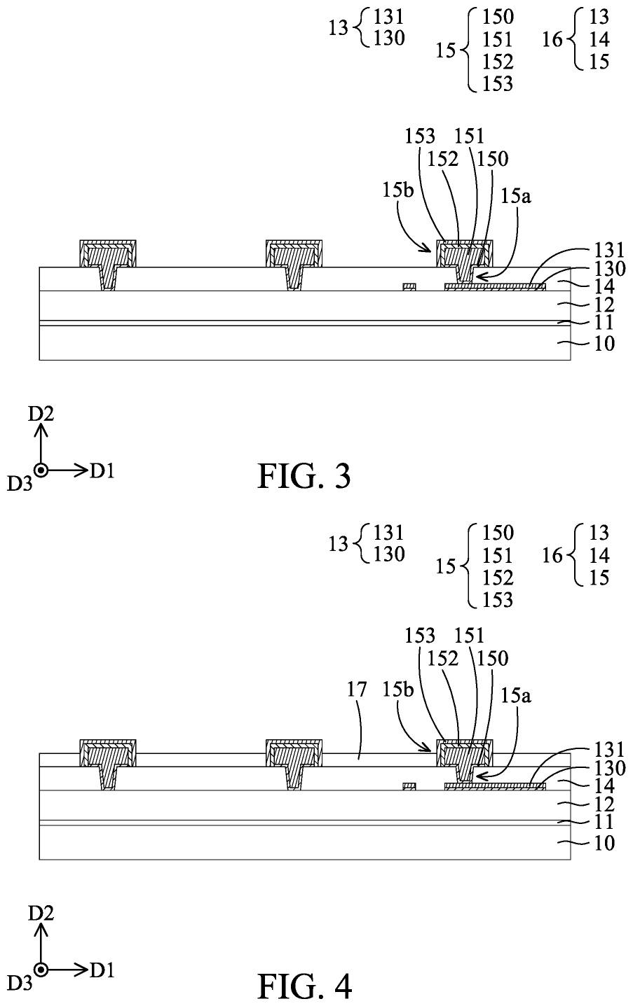

FIGS. 8 to 9 are schematic cross-sectional views showing the electronic device at different formation stages according to some embodiments of the present disclosure. Following the step shown in FIG. 7, the opening 200 is formed in the support layer 20. The opening 200 may include the opening 200a and the opening 200b, wherein the opening 200a and the opening 120a are connected to each other, and the opening 200b and the opening 120b are connected to each other. In other words, in the second direction D2, the opening 200b, the opening 120b, and the opening 140 overlap each other. According to some embodiments, the opening 200b may expose a portion of the surface of the base layer 12. In other words, the width of the opening 200b is greater than the width of the opening 120b. Furthermore, the width of the lower bottom of the opening 200b is greater than the width of the upper bottom of the opening 120b. The width referred to in the present disclosure is measured along the direction D1 perpendicular to the second direction D2.

Following the above step, the bonding element 21 is disposed in the opening 200a of the support layer 20 and the opening 120a of the base layer 12 so that the bonding element 21 is in contact with the first conductive layer 13. In some embodiments, the bonding element 21 may include copper (Cu), aluminum (Al), molybdenum (Mo), silver (Ag), tin (Sn), tungsten (W), gold (Au), chromium (Cr), nickel (Ni), platinum (Pt), other suitable metals or an alloy thereof, the like, or a combination thereof, but the present disclosure is not limited thereto. For example, the bonding element 21 may include a transparent conductive oxide (TCO), such as indium tin oxide (ITO), tin oxide (SnO), zinc oxide (ZnO), indium zinc oxide (IZO), indium gallium zinc oxide (IGZO), indium tin zinc oxide (ITZO), antimony tin oxide (ATO), antimony zinc oxide (AZO), the like, or a combination thereof, but the present disclosure is not limited thereto. In some embodiments, the bonding element 21 is a solder ball. Specifically, the solder ball may be in the opening 120a and the opening 200a to be protected by the base layer 12 and the support layer 20, thereby preventing the service life of the electronic device 1b from reducing by an intermetallic compound that may be formed on the surface of the solder ball and be too hard and brittle.

Following the above step, the external element 22 is bonded to the bonding element 21. In other words, the bonding element 21 penetrates the base layer 12 and the support layer 20 and is in contact with the first conductive layer 13 and the external element 22. In some embodiments, the external element 22 may include a printed circuit board, a flexible circuit board, other suitable external elements, or a combination thereof, but the present disclosure is not limited thereto. After disposing the external element 22, the electrical signal obtained from the circuit layer 16 may be transmitted to the external element 22 through the bonding element 21.

As shown in FIG. 9, following the above step, the second carrier 18 is turned over and is removed. For example, the second carrier 18 may be separated from the circuit layer 16 by removing the adhesive layer 19. In this way, the electronic device 1b for detecting electronic elements may be obtained. Specifically, the electronic device 1b includes the circuit structure 1a, the bonding element 21, and the external element 22. The circuit structure 1a includes the support layer 20, the base layer 12, and the circuit layer 16. The base layer 12 is disposed on the support layer 20. The circuit structure 1a includes the support layer 20, the base layer 12, and the circuit layer 16. The base layer 12 is disposed on the support layer 20. The circuit layer 16 is disposed on the base layer 12, and the circuit layer 16 includes the first conductive layer 13, the first insulating layer 14, and the second conductive layer 15. The first conductive layer 13 is disposed on the base layer 12. The first insulating layer 14 is disposed on the first conductive layer 13. The second conductive layer 15 is disposed on the first insulating layer 14. The bonding element 21 is in contact with the first conductive layer 13. The external element 22 is electrically connected to the circuit layer 16 through the bonding element 21.

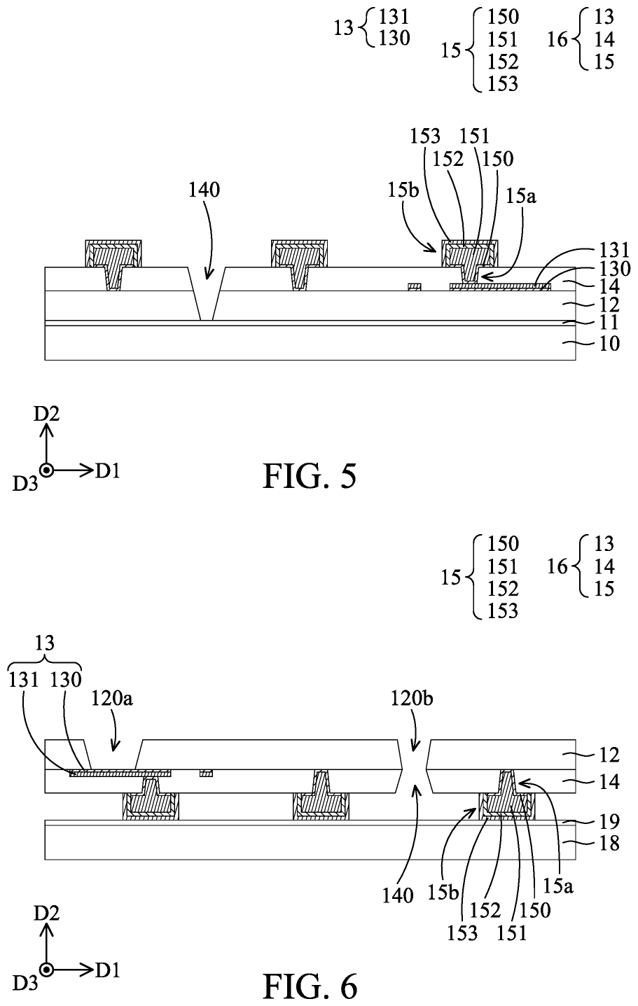

FIG. 10 is a top view of the electronic device according to some embodiments of the present disclosure. As shown in the figure, when viewed from a top view, the surface of the electronic device 1b has a probe for connecting to the object to be tested (that is, the second portion 15b of the second conductive layer 15). When the first insulating layer 14 is partially or completely transparent, the second conductive layer 15 (for example, the first portion 15a) and the first conductive layer 13 disposed inside the first insulating layer 14 may also be observed (as shown in FIG. 10). In some embodiments, the electronic device 1b shown in FIG. 9 is a cross-section view along the line a-a of FIG. 10, but the present disclosure is not limited thereto.

In some embodiments, when viewed from a top view, the second portion 15b of the second conductive layer 15 has the width w1. On the other hand, the first conductive layer 13 includes the third portion 13a as the line segment and the fourth portion 13b as the pad portion, wherein the fourth portion 13b has the width w2. In some embodiments, the width w2 is greater than the width w1. In other words, the electronic device 1b may accurately measure the object to be tested through a narrow probe (i.e., the second portion 15b of the second conductive layer 15) and be electrically connected to the external element 22 through a wide pad (i.e., the fourth portion 13b of the first conductive layer 13).

It should be noted that the possible configurations of the electronic device 1b shown in FIG. 10 are only used to make the present disclosure clearer and easier to understand but not intended to limit the present disclosure. In other words, the number, relative positions, sizes, etc. of the elements of the electronic device 1b shown in FIG. 10 may be adjusted according to actual needs and are not limited to those shown in the figure. In the following, possible aspects of the electronic device 1b is provided according to various embodiments of the present disclosure.

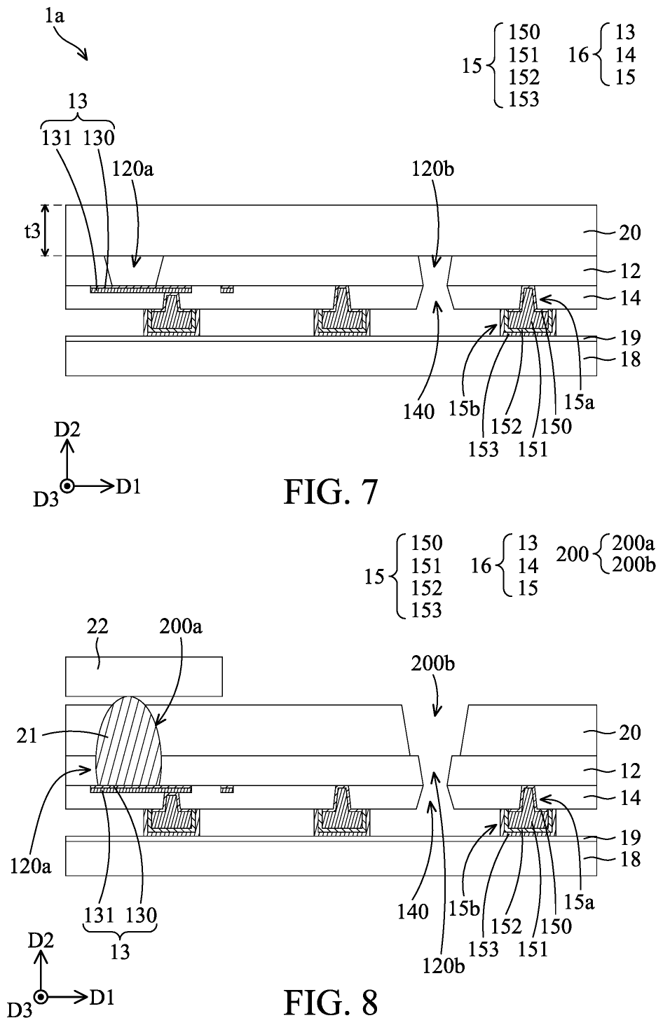

FIG. 11 is a schematic cross-sectional view along the line a-a of FIG. 9 according to other embodiments of the present disclosure. As shown in the figure, in some embodiments, before disposing the support layer 20 on the side of the base layer 12 away from the circuit layer 16, the support layer 20 may include the protrusion 201. Following the above step, after disposing the support layer 20 on the side of the base layer 12 away from the circuit layer 16, the protruding portion 201 may be positioned between the external element 22 and the main body of the support layer 20, so that the main body of the support layer 20 is spaced apart from the external element 22 by the distance d1. In other words, the protrusion 201 is disposed on the side of the support layer 20 away from the base layer 12. During the operation of the electronic device 1b, the distance d1 from the protruding portion 201 may be used as a buffer space to mitigate the impact of the pressure on the circuit structure 1a to the external elements 22.

For example, during the process of forming the support layer 20, a portion of the support layer 20 may be made to protrude outward to form the protrusion 201. Alternatively, the protrusion 201 may also be formed by thinning a portion of the support layer 20. In other words, the protruding portion 201 may be integrally formed with the main body (i.e., the portion other than the protruding portion 201) of the support layer 20, but the present disclosure is not limited thereto. In other embodiments, the protruding portion 201 may also be adhered to the support layer 20 in an adhesive manner.

In some embodiments, the material of protrusion 201 may be similar or the same as to the main body of support layer 20. In some embodiments, the elongation of the protrusion 201 may be 10%, 15%, 20%, 25%, 30%, 35%, 40%, 45%, 50%, or any value or range between the above values, but the present disclosure is not limited thereto. The elongation of the protrusion 201 is smaller than the elongation of the first insulating layer 14.

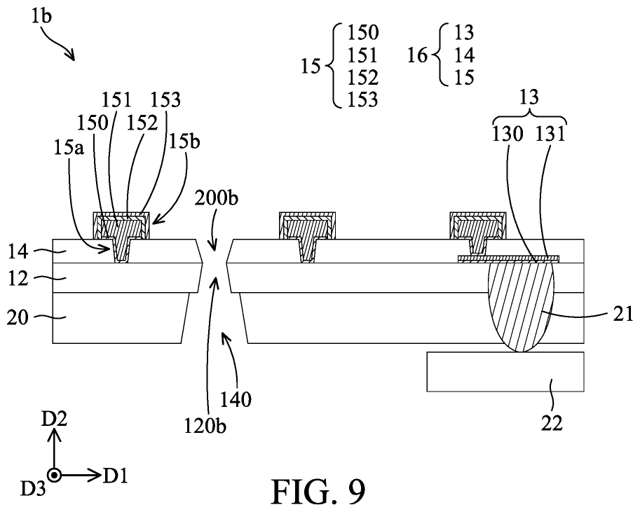

FIG. 12 is a schematic cross-sectional view along the line a-a of FIG. 9 according to further embodiments of the present disclosure. As shown in the figure, before disposing the support layer 20 on the side of the base layer 12 away from the circuit layer 16, the sensing element 23 is disposed in the support layer 20. Following the above step, after disposing the support layer 20, the sensing element 23 is on the side of the support layer 20 adjacent to the circuit layer 16, and the opening 120a of the base layer 12 and the opening 140 of the circuit layer 16 expose the sensing element 23.

In some embodiments, the sensing element 23 may include an optical distance measuring element for measuring distance, a counting element for counting the number of detections, a switching element for turning on and off the circuit layer, a photosensitive element for capturing images, a charge coupled device (CCD), other suitable sensing elements, or a combination thereof, but the present disclosure is not limited thereto. Taking the sensing element 23 including an optical distance measuring element for measuring distance as an example, in such cases, it may be ensured that the probe of the circuit layer 16 (i.e., the second portion 15b of the second conductive layer 15) may be in contact with the object to be tested at an appropriate distance or pressure. Therefore, the quality of electrical testing is ensured. In the case where the sensing element 23 includes a plurality of optical distance measuring elements for measuring distance, the level between the circuit layer 16 and the object to be tested may also be ensured to further ensure the quality of electrical testing.

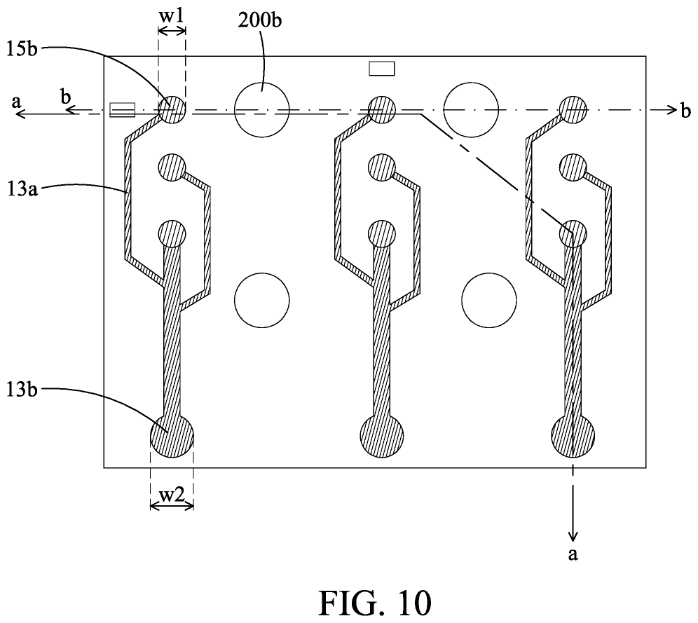

FIG. 13 is a schematic cross-sectional view along the line a-a of FIG. 9 according to further embodiments of the present disclosure. In these embodiments, the support layer 20 may include the protrusion 201, and the sensing element 23 may be disposed in the support layer 20. In such cases, the electronic device 1b may be more accurately aligned through the sensing element 23 such as the distance measuring element, and the protruding portion 201 may mitigate the impact during the electrical testing, thereby effectively extending the service life of the device.

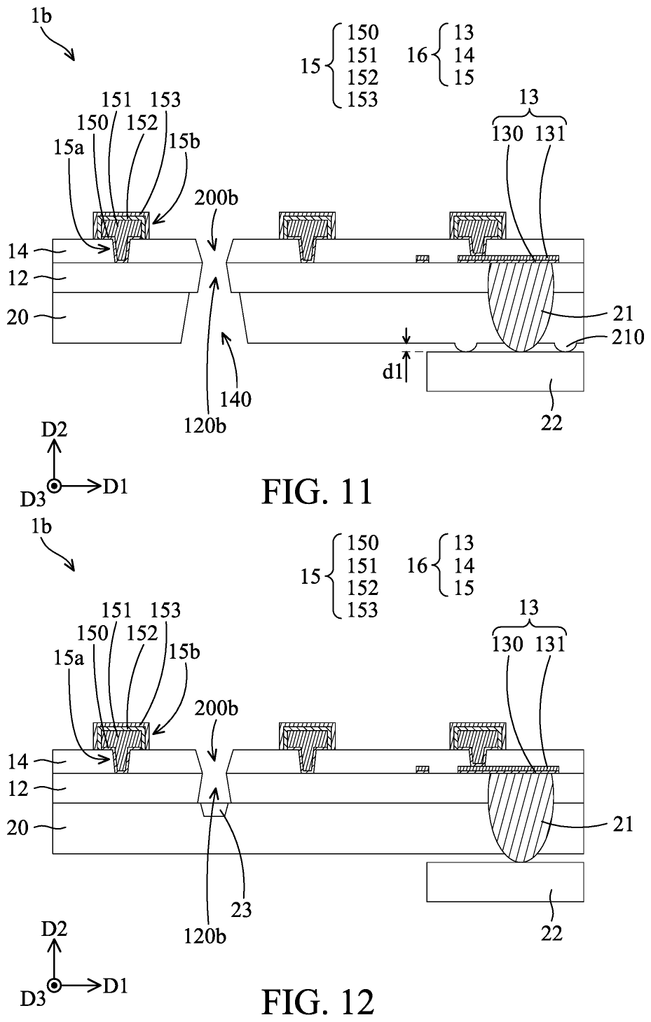

FIG. 14 is a schematic cross-sectional view along the line b-b of FIG. 9 according to some embodiments of the present disclosure. As shown in the figure, in some embodiments, the electronic device 1b further includes the marking element 24, and the marking element 24 may be disposed in the first insulating layer 14 of the circuit layer 16, or be disposed in the base layer 12. Specifically, the marking element 24 may be used as a target for the alignment process to assist in the alignment between the electronic device 1b and the object to be tested. In some embodiments, the marking element 24 may include colored ink, colored paint, metal, other suitable colored elements, or a combination thereof, but the present disclosure is not limited thereto. According to some embodiments, the marking element 24 may be in the same layer as part of the second conductive layer 15.

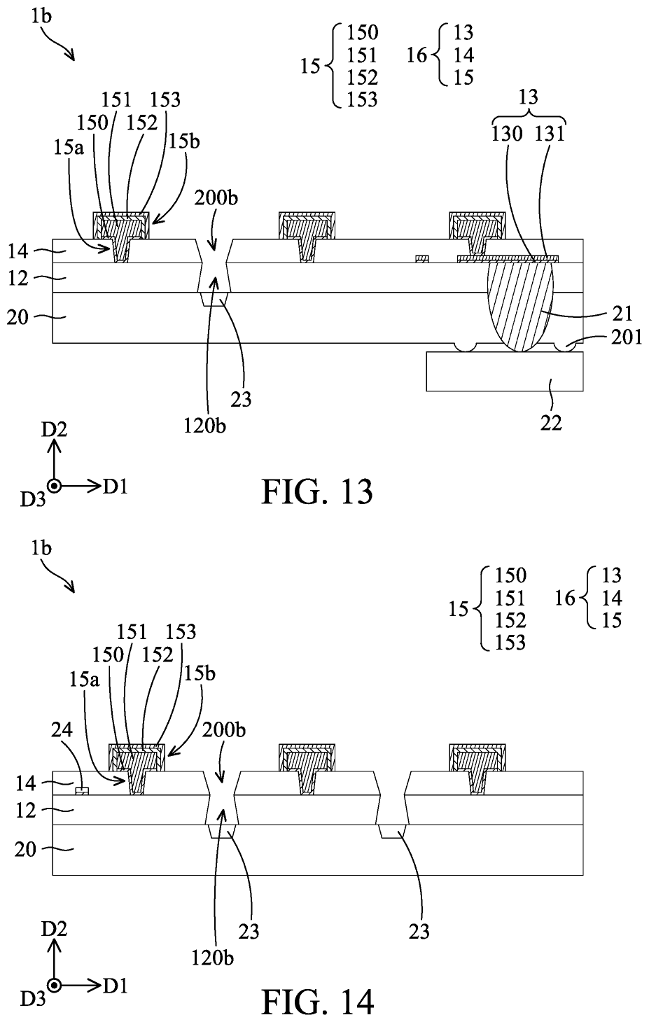

FIGS. 15 to 16 are schematic cross-sectional views showing the electronic device at different formation stages according to further embodiments of the present disclosure. Specifically, the step shown in FIG. 15 follows the step shown FIG. 7. As shown in the figure, following the above step, the first bonding element 210 is disposed in the opening 120a of the base layer 12. In some embodiments, the first bonding element 210 may include copper (Cu), aluminum (Al), molybdenum (Mo), silver (Ag), tin (Sn), tungsten (W), gold (Au), chromium (Cr), nickel (Ni), platinum (Pt), other suitable metals, an alloy thereof, the like, or a combination thereof, but the present disclosure is not limited thereto. For example, the first bonding element 210 may include a transparent conductive oxide (TCO), such as indium tin oxide (ITO), tin oxide (SnO), zinc oxide (ZnO), indium zinc oxide (IZO), indium gallium zinc oxide (IGZO), indium tin zinc oxide (ITZO), antimony tin oxide (ATO), antimony zinc oxide (AZO), the like, or a combination thereof, but the present disclosure is not limited thereto. In some embodiments, the first bonding element 210 is a solder ball, and the solder ball is in the opening 120a.

Following the above step, the compression element 25 is disposed on the base layer 12, and the support layer 20 is disposed on the compression element 25. Specifically, the compression element 25 is between the support layer 20 and the base layer 12 and separates the support layer 20 and the base layer 12 by a distance d2. During the operation of the electronic device 1b, the distance d2 from the compression element 25 may be used as a buffer space to mitigate the impact of the pressure on the circuit structure 1a to the external elements 22. In some embodiments, the elongation of the compression element 25 may be 10%, 15%, 20%, 25%, 30%, 35%, 40%, 45%, 50%, or any value or range between the above values, but the present disclosure is not limited thereto. In some embodiments, the first insulation layer 14 is closer to the object to be tested than the compression element 25. Therefore, the elongation of the first insulating layer 14 may be greater than the elongation of the compression element 25. That is, the elongation of the compression element 25 is smaller than the elongation of the first insulating layer 14 so that the circuit structure (or electronic device) may more effectively mitigate collisions during testing, thereby further extending the service life of the entire device. That is, the elongation of the compression element 25 is smaller than the elongation of the first insulating layer 14.

In some embodiments, the material of the compression element 25 may be similar or the same as the material of the support layer 20, but the present disclosure is not limited thereto. In some embodiments, the compression element 25 may also be disposed in the base layer 12 before disposing the support layer 20, for example, at a location in the base layer 12 that may bear greater pressure. According to some embodiments, the compression element 25 may be adhesive, such as a glue layer.

Following the above step, the opening 200 is formed in the support layer 20. The opening 200 may include the opening 200a, and the opening 200a and the first bonding element 210 in the opening 120a are connected to each other. It should be noted that in the embodiments shown in FIG. 15, the sensing element 23 may be disposed in the support layer 20. The description of the sensing element 23 may be referred to the above description and is omitted here.

As shown in FIG. 16, following the above step, the second carrier 18 is turned over and is removed. Then, the second bonding element 211 is disposed in the opening 200a so that the second bonding element 211 is in contact with the first bonding element 210. In some embodiments, the second bonding element 211 may include copper (Cu), aluminum (Al), molybdenum (Mo), silver (Ag), tin (Sn), tungsten (W), gold (Au), chromium (Cr), nickel (Ni), platinum (Pt), other suitable metals, an alloy thereof, the like, or a combination thereof, but the present disclosure is not limited thereto. For example, the second bonding element 211 may include a transparent conductive oxide (TCO), such as indium tin oxide (ITO), tin oxide (SnO), zinc oxide (ZnO), indium zinc oxide (IZO), indium gallium zinc oxide (IGZO), indium tin zinc oxide (ITZO), antimony tin oxide (ATO), antimony zinc oxide (AZO), the like, or a combination thereof, but the present disclosure is not limited thereto. In some embodiments, the material of the second bonding element 211 may be similar or the same as that of the first bonding element 210, but the present disclosure is not limited thereto. In some implementations, the first bonding element 210 and the second bonding element 211 may be collectively referred to as the bonding element 21. In some embodiments, the second bonding element 211 may be a solder ball, but the present disclosure is not limited thereto.

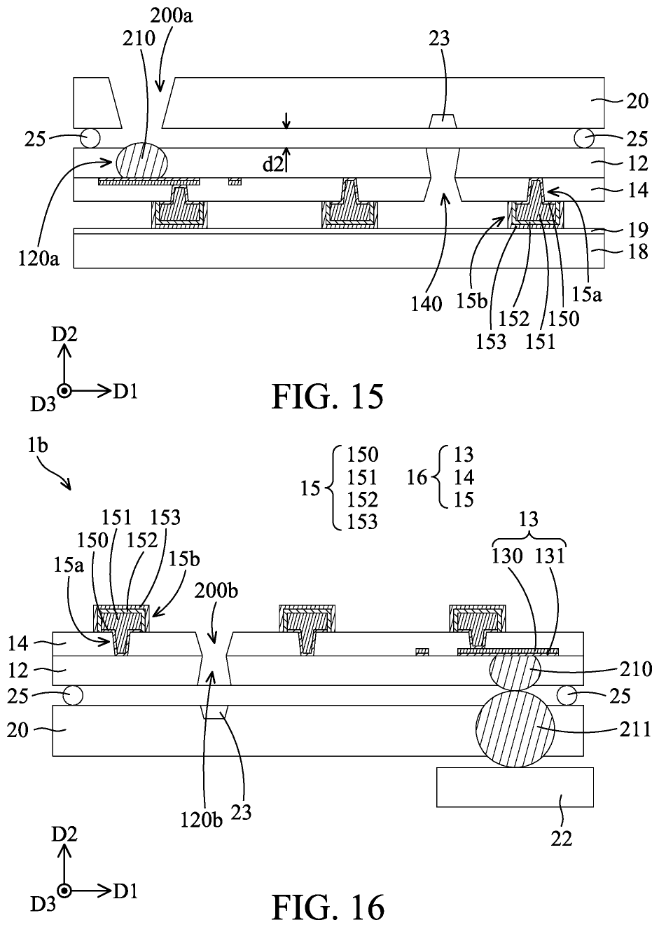

FIG. 17 is a schematic cross-sectional view showing the electronic device according to further embodiments of the present disclosure. As shown in the figure, in some embodiments, the first conductive layer 13 of the circuit structure 1a protrudes from the side wall of the first insulating layer 14 and is electrically connected to the external element 22 through the bonding element 21. For example, in these embodiments, an anisotropic conductive film (ACF) may be used as the bonding element 21 to avoid the problem of intermetallic compounds generated by using, for example, solder paste. In such cases, the base layer 12 may not have the opening 120a for accommodating the bonding element 21, and the support layer 20 may not have the opening 200a for accommodating the bonding element 21. In some embodiments, the external element 22 electrically connected to the first conductive layer 13 through the anisotropic conductive film may be a flexible circuit board, but the present disclosure is not limited thereto.

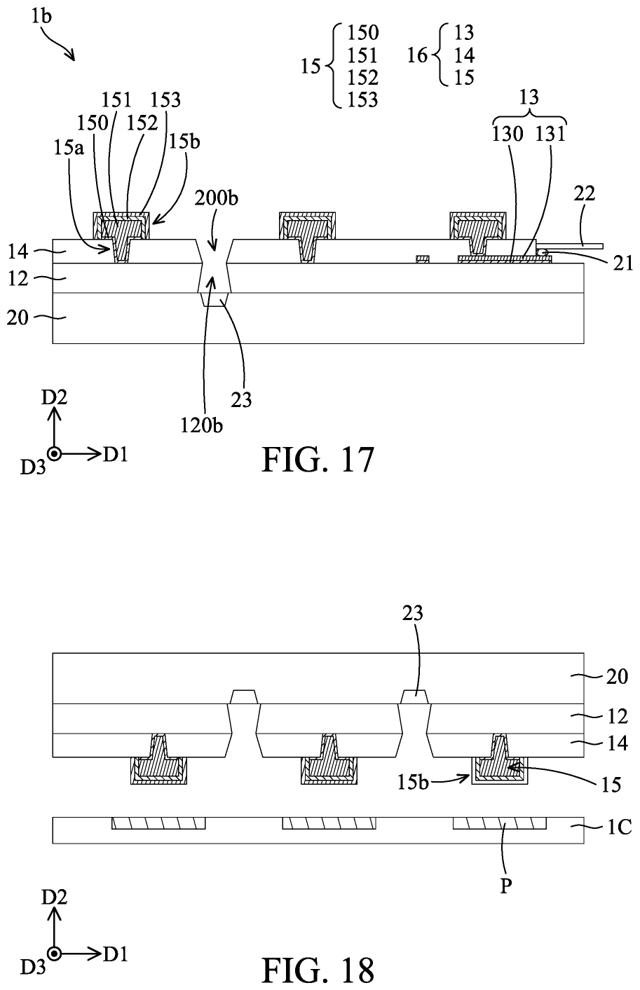

FIG. 18 is a schematic diagram showing the use of the electronic device according to some embodiments of the present disclosure. As shown in the figure, during use of the electronic device 1b, the probes in the circuit layer 16 of the electronic device 1b (i.e., the second portions 15b of the second conductive layer 15) each correspond to one of the pads P (or other conductive pieces) of the object 1c to be tested to measure the electrical properties of the object 1c to be tested. In an embodiment in which the electronic device 1b includes the sensing element 23, the distance between the electronic device 1b and the object 1c to be tested may be determined (for example, by optical distance measurement) by the sensing element 23 to accurately measure the electrical properties of the object 1c to be tested. In addition, it may avoid exerting excessive pressure on the electronic device 1b during the process of making the electronic device 1b be in contact with the object 1c to be tested, thereby causing damage to the electronic device 1b.

In summary, the present disclosure provides the circuit structure 1a, the electronic device 1b, and a manufacturing method of the electronic device 1b to effectively solve at least some of the problems in the prior art. Specifically, compared with the sensing device of the prior art, the circuit structure 1a and the electronic device 1b of the present disclosure may have a higher measurement accuracy, longer service life, and lower cost.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A circuit structure, comprising:
a support layer;
a base layer disposed on the support layer; and
a circuit layer disposed on the base layer, wherein the circuit layer comprises:
a first conductive layer disposed on the base layer;
a first insulating layer disposed on the first conductive layer; and
a second conductive layer disposed on the first insulating layer,
wherein an elongation of the support layer is less than an elongation of the base layer.

2. The circuit structure as claimed in claim 1, wherein the elongation of the support layer is less than an elongation of the first insulating layer.

3. The circuit structure as claimed in claim 1, wherein the elongation of the base layer is less than an elongation of the first insulating layer.

4. The circuit structure as claimed in claim 1, wherein a thickness of the support layer is greater than a thickness of the base layer.

5. The circuit structure as claimed in claim 1, wherein a thickness of the support layer is greater than a thickness of the first insulating layer.

6. The circuit structure as claimed in claim 1, wherein the support layer comprises a protrusion, and the protrusion is disposed on a side of the support layer away from the base layer.

7. The circuit structure as claimed in claim 1, further comprising a sensing element disposed on the support layer, wherein the base layer and the circuit layer have an opening, and the opening exposes the sensing element.

8. The circuit structure as claimed in claim 1, wherein the second conductive layer comprises a first portion and a second portion, the first portion penetrates the first insulating layer and is disposed on the first conductive layer, and the second portion is disposed on the first portion.

9. The circuit structure as claimed in claim 1, further comprising a compression element, and the compression element is disposed between the base layer and the support layer or is disposed in the base layer.

10. The circuit structure as claimed in claim 9, wherein an elongation of the compression element is less than an elongation of the first insulating layer.

11. The circuit structure as claimed in claim 1, further comprising a marking element, and the marking element is disposed in the base layer or the first insulating layer.

12. An electronic device, comprising:
a circuit structure, comprising:
a support layer;
a base layer disposed on the support layer;
a circuit layer disposed on the base layer, wherein the circuit layer comprises:
a first conductive layer disposed on the base layer;
a first insulating layer disposed on the first conductive layer; and
a second conductive layer disposed on the first insulating layer;
a bonding element in contact with the first conductive layer; and
an external element electrically connected to the circuit layer through the bonding element,
wherein an elongation of the support layer is less than an elongation of the base layer.

13. The electronic device as claimed in claim 12, wherein the bonding element penetrates the base layer and the support layer and is in contact with the first conductive layer and the external element.

14. A manufacturing method of an electronic device, comprising:
disposing a first conductive layer on a base layer;
disposing a first insulating layer on the first conductive layer;
forming a second conductive layer on the first conductive layer, wherein the first conductive layer, the first insulating layer, and the second conductive layer collectively form a circuit layer;
disposing a support layer on a side of the base layer away from the circuit layer, wherein an elongation of the support layer is less than an elongation of the first insulating layer;
disposing a bonding element in the support layer so that the bonding element is in contact with the first conductive layer; and
bonding an external element to the bonding element.

15. The manufacturing method of the electronic device as claimed in claim 13, wherein the elongation of the support layer is less than an elongation of the first insulating layer.

16. The manufacturing method of the electronic device as claimed in claim 13, wherein the elongation of the base layer is less than an elongation of the first insulating layer.

17. The manufacturing method of the electronic device as claimed in claim 13, wherein before disposing the support layer, a sensing element is disposed in the support layer, and after disposing the support layer, the sensing element is on the side of the support layer adjacent to the circuit layer.

18. The manufacturing method of the electronic device as claimed in claim 13, wherein before disposing the support layer, a compression element is disposed on the base layer, and after disposing the support layer, the compression element is between the base layer and the support layer.

19. The manufacturing method of the electronic device as claimed in claim 13, wherein a compression element is disposed in the base layer before disposing the support layer.

20. The manufacturing method of the electronic device as claimed in claim 13, further comprising:
before disposing the first conductive layer on the base layer, forming the base layer on a first carrier;
before disposing the support layer on the side of the base layer away from the circuit layer, bonding a second carrier to the circuit layer;
turning over the second carrier; and
removing the first carrier.
